(19) United States
(12) Patent Application Publication
(10) Pub. No.: US 2025/0240975 A1
(43) Pub. Date: Jul. 24, 2025

(54) SEMICONDUCTOR DEVICE AND MANUFACTURING METHOD THEREOF

(71) Applicant: Powerchip Semiconductor Manufacturing Corporation, Hsinchu (TW)

(72) Inventor: Zih-Song Wang, Nantou County (TW)

(73) Assignee: Powerchip Semiconductor Manufacturing Corporation, Hsinchu (TW)

(21) Appl. No.: 18/621,025

(22) Filed: Mar. 28, 2024

(30) Foreign Application Priority Data
Jan. 24, 2024 (TW) 113102725

(51) Int. Cl. H10B 61/00; H01F 10/32; H10N 50/10

(52) U.S. Cl. CPC H10B 61/22; H01F 10/3272; H10N 50/10

(57) ABSTRACT

Provided are a semiconductor device and its manufacturing method. The semiconductor device includes first structures extending in a first direction and spaced apart from each other in a second direction intersecting the first direction, second structures located above the first structures, extending in the second direction, and spaced apart from each other in the first direction, and barrier layers located between the first and second structures, extending in the second direction, and spaced apart from each other in the first direction. Each first structure includes a word line, a selector on the word line, and at least one SAF structure on the selector. Each second structure includes a bit line crossing over the SAF structures in the second direction, free layers between the bit line and the SAF structures, and spacers respectively located on opposite sidewalls of the bit line and including portions covering sidewalls of the free layers.

### CROSS-REFERENCE TO RELATED APPLICATION

This application claims the priority benefit of Taiwan application serial no. 113102725, filed on Jan. 24, 2024. The entirety of the above-mentioned patent application is hereby incorporated by reference herein and made a part of this specification.

### BACKGROUND

### Technical Field

The disclosure relates to a semiconductor device and a manufacturing method thereof.

### Description of Related Art

A magnetic random access memory (MRAM) delivers performance comparable to a volatile static random access memory (SRAM) and density similar to a volatile dynamic random access memory (DRAM), while the MRAM consumes lower power. In comparison to a non-volatile flash memory, the MRAM offers faster access time and exhibits less degradation over time, whereas the flash memory is constrained by a finite number of rewrites.

The fundamental memory unit in the MRAM is commonly known as a magnetic tunneling junction (MTJ). For instance, the MTJ may include a sandwich structure composed of two ferromagnetic layers and an insulation layer in between (e.g., a free layer/a barrier layer/a pinned layer). When a magnetization direction of the free layer is the same as that of the pinned layer (referred to as a ‘parallel state’), the resistance value measured by upper and lower electrodes of the MTJ is smaller; conversely, when the magnetization direction of the free layer is opposite to that of the pinned layer (known as an ‘antiparallel state’), the resistance value measured by the upper and lower electrodes of the MTJ is larger. This enables data storage through the differences in the resistance values.

However, with electronic devices advancing towards smaller sizes and higher performance, the current MRAM manufacturing process may face challenges that hinder its compatibility with the needs of current or future electronic devices. For instance, during the formation of the barrier layer, damage caused by ion-beam etch (IBE) to the barrier layer or contamination from re-deposition significantly impacts the current or expected performance of the MRAM. Therefore, people skilled in the pertinent field are continually working to enhance the MRAM manufacturing process.

### SUMMARY

The disclosure provides a semiconductor device and a manufacturing method thereof. In an embodiment of the disclosure, spacers on opposite sidewalls of a bit line includes portions covering first sidewalls of free layers which are opposite to each other in a first direction. Consequently, during the formation of a barrier layer, damage to the barrier layer due to IBE is kept at a distance from a region of the free layer overlapping the bit line (i.e., an effective region), so that the performance of the semiconductor device remains unaffected.

According to an embodiment of the disclosure, a semiconductor device is provided, and the semiconductor device includes a plurality of first structures, a plurality of second structures, and a plurality of barrier layers. The first structures extend in a first direction and are spaced apart from each other in a second direction intersecting the first direction. Each of the first structures includes a word line, a selector on the word line, and at least one synthetic antiferromagnetic (SAF) structure on the selector. The second structures are disposed above the first structures, extend in the second direction, and are spaced apart from each other in the first direction. Each of the second structures includes a bit line crossing over a plurality of the SAF structures in the second direction, a plurality of free layers between the bit line and the SAF structures, and a plurality of spacers on opposite sidewalls of the bit line. The free layers are disposed at an intersection where the bit line and the word line intersect. The spacers include portions covering first sidewalls of the free layers that are opposite to each other in the first direction. The barrier layers are disposed between the first structures and the second structures, extend in the second direction, and are spaced apart from each other in the first direction.

In some embodiments of the disclosure, the portions of the spacers cover top surfaces of the underlying barrier layers.

In some embodiments of the disclosure, in each of the first structures, the number of the at least one SAF structure is plural, and the SAF structures are spaced apart from each other in the first direction.

In some embodiments of the disclosure, the portions of the spacers are overlapped with the barrier layers and the SAF structures in a third direction perpendicular to the first direction and the second direction.

In some embodiments of the disclosure, the barrier layers include sidewalls coplanar with sidewalls of the SAF structures.

In some embodiments of the disclosure, the semiconductor device further includes a plurality of insulation layers. Each of the insulation layers is disposed below the bit line and between the free layers, and the insulation layers cover second sidewalls of the free layers that are opposite to each other in the second direction.

According to an embodiment of the disclosure, a semiconductor device is provided, and the semiconductor device includes a plurality of first structures, a plurality of second structures, and at least one barrier layer. The first structures extend in a first direction and are spaced apart from each other in a second direction intersecting the first direction. Each of the first structures includes a word line, a selector on the word line, and a SAF structure on the selector. The second structures are disposed above the first structures, extend in the second direction, and are spaced apart from each other in the first direction. Each of the second structures includes a bit line crossing over a plurality of the SAF structures in the second direction and a plurality of free layers between the bit line and the SAF structures. The free layers are disposed at an intersection where the bit line and the word line intersect. The at least one barrier layer is disposed between the first structures and the second structures.

In some embodiments of the disclosure, the at least one barrier layer is a continuous single film layer.

In some embodiments of the disclosure, the number of the at least one barrier layer is plural, the barrier layers are spaced apart from each other in the first direction and the second direction, and each of the barrier layers is disposed between one of the first structures and one of the second structures.

According to an embodiment of the disclosure, a manufacturing method of a semiconductor device is provided, and the manufacturing method includes following steps. A plurality of first structures are formed, where the first structures extend in a first direction and are spaced apart from each other in a second direction intersecting the first direction, and each of the first structures includes a word line, a selector on the word line, and at least one SAF structure on the selector. A barrier material layer covering the first structures is formed. A plurality of second structures are formed on the barrier material layer, where the second structures extend in the second direction and are spaced apart from each other in the first direction, each of the second structures includes a bit line crossing over a plurality of the SAF structures in the second direction, a plurality of free layers between the bit line and the SAF structures, and a plurality of spacers respectively located on opposite sidewalls of the bit line, where the free layers are formed at an intersection where the bit line and the word line intersect, and the spacers include portions covering first sidewalls of the free layers that are opposite to each other in the first direction. A portion of the barrier material layer exposed by the second structures is removed to form a plurality of barrier layers, where the barrier layers extend in the second direction and are spaced apart from each other in the first direction.

In some embodiments of the disclosure, the portions of the spacers cover top surfaces of the underlying barrier layers.

In some embodiments of the disclosure, the manufacturing method further includes the following step. In the step of removing the portion of the barrier material layer exposed by the second structures, a portion of at least one synthetic antiferromagnetic structure located below the removed portion of the barrier material is also removed, so that the at least one SAF structure in each of the first structures becomes a plurality of the SAF structures that are spaced apart from each other in the first direction.

In view of the above, in the semiconductor device and the manufacturing method thereof according to one of the embodiments of the disclosure, the spacers on the opposite sidewall of the bit line include the portions covering the first sidewalls of the free layers that are opposite to each other in the first direction. As such, during the process of manufacturing the barrier layer, damages to the barrier layer by the IBE are far from the region of the free layer overlapping the bit line (i.e., the effective region), and thus the performance of the semiconductor device remains unaffected.

To make the above more comprehensible, several embodiments accompanied with drawings are described in detail as follows.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 to FIG. 6 are schematic cross-sectional views of a manufacturing method of a semiconductor device according to an embodiment of the disclosure.

FIG. 7A is a schematic cross-sectional view taken along a sectional line X-X′ depicted in FIG. 6 according to an embodiment of the disclosure.

FIG. 7B is a schematic cross-sectional view taken along a sectional line Y-Y′ depicted in FIG. 6 according to an embodiment of the disclosure.

FIG. 8 is a schematic cross-sectional view of a semiconductor device according to another embodiment of the disclosure.

FIG. 9 is a schematic cross-sectional view of a semiconductor device according to another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used to represent the same drawings or similar parts in the accompanying and description, and the description of the same technical content is omitted. The description of the omitted part may be derived from the previous embodiment and will not be repeated in the following embodiments.

It should be understood that when an element is referred to as being “on” or “connected to” another element, it can be directly on or connected to the another element, or an intermediate element may also be present. By contrast, when an element is referred to as being “directly on” or “directly connected to” another element, no intermediate element is present. As used herein, being “connected” may refer to a physical and/or electrical connection. Furthermore, being “electrically connected” or “coupled” may refer to the presence of other elements between the two elements. “Electrical connections” as used herein may include physical connections (e.g., connections through cables) and physical disconnections (e.g., wireless connections).

The terminology “about,” “approximately,” or “substantially” used herein includes the average of the stated value and an acceptable range of deviations from the particular value as determined by those skilled in the art. For instance, the terminology “about” may refer to as being within one or more standard deviations of the stated value, or within +30%, +20%, +10%, or +5%. Furthermore, the terminology “about,” “approximately,” or “substantially” as used herein may be chosen from a range of acceptable deviations or standard deviations depending on the optical properties, etching properties, or other properties, rather than one standard deviation for all properties.

The terminologies and language used herein merely serve to describe exemplary embodiments and do not limit the disclosure. In such cases, the singular includes the plural unless the context explains otherwise.

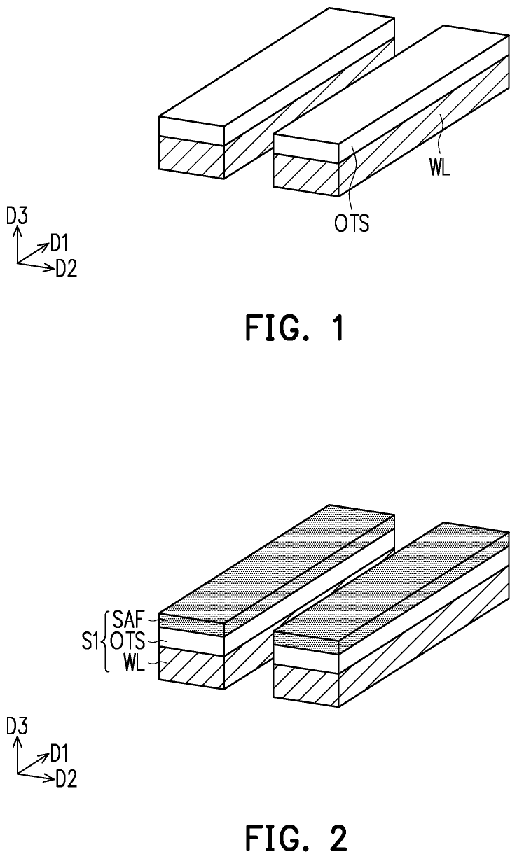

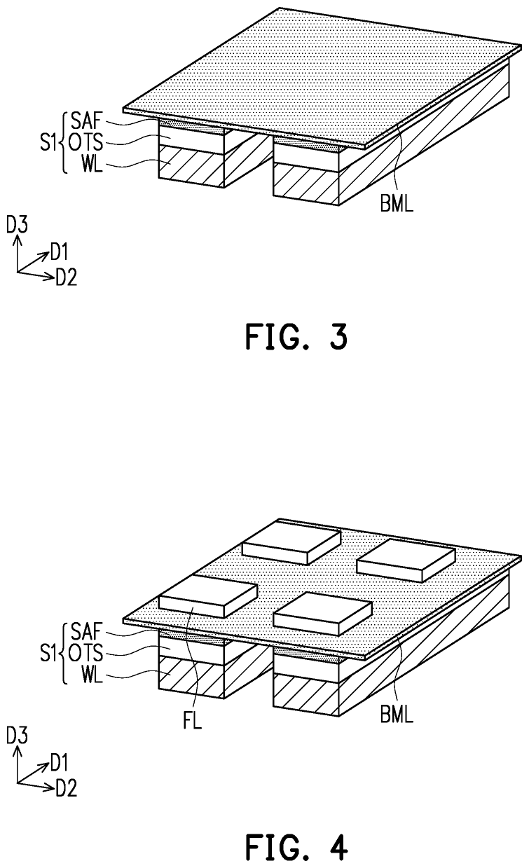

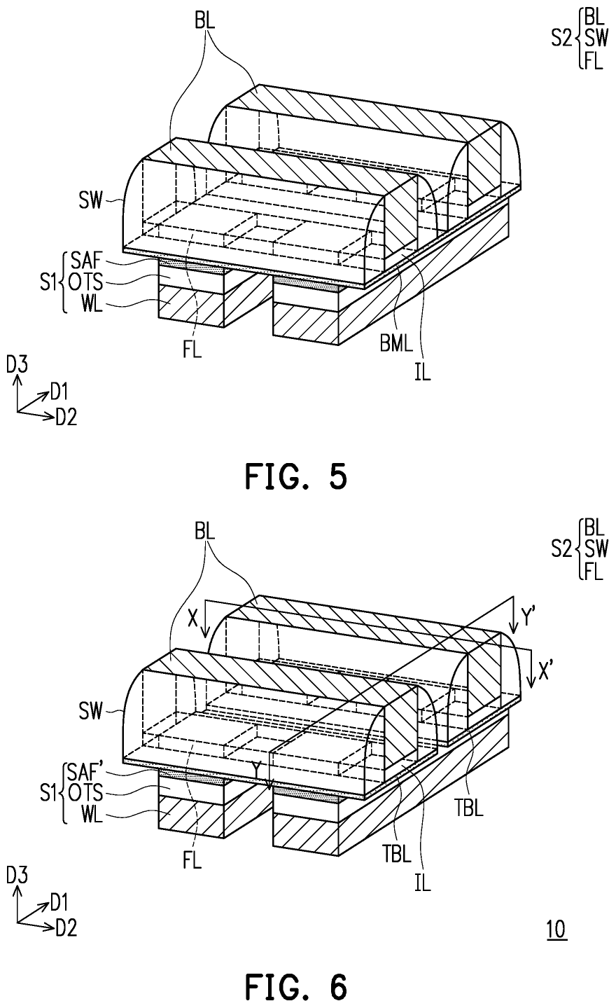

FIG. 1 to FIG. 6 are schematic cross-sectional views of a manufacturing method of a semiconductor device according to an embodiment of the disclosure. FIG. 7A is a schematic cross-sectional view taken along a sectional line X-X′ depicted in FIG. 6 according to an embodiment of the disclosure. FIG. 7B is a schematic cross-sectional view taken along a sectional line Y-Y′ depicted in FIG. 6 according to an embodiment of the disclosure.

In some embodiments, the manufacturing method of a semiconductor device (such as a semiconductor device 10 shown in FIG. 6) may include following steps.

Firstly, as shown in FIG. 2, a plurality of first structures S1 are formed, and the first structures S1 extend in a first direction D1 and are spaced apart from each other in a second direction D2 intersecting the first direction D1. Each first structure S1 includes a word line WL, a selector OTS on the word line WL, and at least one synthetic antiferromagnetic (SAF) structure SAF on the selector OTS. The word line WL may include a conductive material, such as metal or metal alloys. The metal and the metal alloys may include, for instance, Cu, Al, Ti, Ta, W, Pt, Cr, Mo, or alloys thereof. The selector OTS may include an ovonic threshold switch (OTS). The selector OTS may include a phase change material, such as GeSbTe (GST). The SAF structure SAF may include a plurality of layers of different materials. For instance, the SAF structure SAF may include a stack of one or more ferromagnetic layers and one or more non-magnetic layers. For instance, the SAF structure SAF may be formed by a non-magnetic layer sandwiched between two ferromagnetic layers or may be a stack of alternating non-magnetic layers and ferromagnetic layers. The ferromagnetic layer may, for instance, be made of following materials: Co, Fe, Ni, Pt, CoPt, CoFe, NiFe, CoFeB, CoFeBW, alloys thereof, or combinations thereof. The non-magnetic layer may, for instance, be made of following materials: Cu, Ru, Ir, Pt, W, Ta, Mg, or combinations thereof.

In some embodiments, the first structures S1 may be formed on a substrate (not shown). The substrate may include a semiconductor substrate, a semiconductor on insulator (SOI) substrate, and/or a device layer and an interconnection layer formed on the semiconductor substrate or the SOI substrate.

Semiconductor materials in the semiconductor substrate or the SOI substrate may include elemental semiconductors, alloy semiconductors, or compound semiconductors. For instance, the elemental semiconductors may include Si or Ge. The alloy semiconductors may include SiGe, SiGeC, and so on. The compound semiconductors may include SiC, III-V group semiconductor materials, or II-VI group semiconductor materials. The III-V group semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI group semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of either a first type or a dopant of a second type that complements the first type. For instance, the first type may be P-type, and the second type may be N-type.

The device layer may include active devices such as metal oxide semiconductor field effect transistors (MOSFET), passive devices such as resistors, inductors, or capacitors, or combinations thereof. The interconnection layer may include a dielectric layer and/or a conductor layer and/or conductive vias formed by front-end-of-line (FEOL) and/or back-end-of-line (BEOL) processes. The dielectric layer may include dielectric materials, such as oxides (for instance, silicon oxide) or nitrides (for instance, silicon nitride). The conductor layer and the conductive vias may each include conductive materials, e.g., metal or metal alloys. The metal and the metal alloys may include, for instance, Cu, Al, Ti, Ta, W, Pt, Cr, Mo, or alloys thereof.

In some embodiments, the first structures S1 may be formed through following steps. First, with reference to FIG. 1, a plurality of word lines WL extending in the first direction D1 and spaced apart from each other in the second direction D2 are formed, and a selector OTS is formed on each word line WL. In some embodiments, a word line material layer (not shown) and a selector material layer (not shown) may be sequentially formed on the substrate, and then a patterning process is performed on the word line material layer and the selector material layer to form the word lines WL and the selectors OTS.

Next, an SAF structure SAF is formed on each selector OTS. In some embodiments, an SAF material layer (not shown) may be formed on the selectors OTS, and ion-beam etch (IBE) is performed to pattern the SAF material layer to form the SAF structure SAF.

Then, with reference to FIG. 2 and FIG. 3, a barrier material layer BML covering the first structures S1 is formed. The barrier material layer BML includes materials such as MgO, AlO, AlN, SrTiO₃, and so forth. In some embodiments, before the barrier material layer BML is formed, insulation layers (not shown) may be formed among the first structures S1. After that, the barrier material layer BML covering the first structures S1 is formed on the insulation layers.

Subsequently, a plurality of second structures (e.g., the second structure S2 shown in FIG. 5) are formed on the barrier material layer BML. In some embodiments, the second structures may be formed on the barrier material layer BML through performing following steps.

Firstly, with reference to FIG. 3 and FIG. 4, a plurality of free layers FL are formed on the barrier material layer BML. In some embodiments, the free layers FL may be spaced apart from each other in the first direction D1 and the second direction D2, and may overlap the first structures S1 in a third direction D3 perpendicular to the first direction D1 and the second direction D2. The free layers FL may include one or more of the following ferromagnetic materials: cobalt iron boron (CoFeB), cobalt palladium (CoPd), cobalt iron (CoFe), cobalt iron boron tungsten (CoFeBW), nickel iron (NiFe), Ru, alloys thereof, or combinations thereof. The free layers FL may be of a single-layer structure or a multi-layer structure. In some embodiments, the free layers FL may be formed by forming a free material layer (not shown) on the barrier material layer BML and then patterning the free material layer by IBE to form the free layers FL.

Next, with reference to FIG. 4 and FIG. 5, bit lines BL may be formed on the free layers FL, and a plurality of spacers SW may be formed on opposite sidewalls of the bit lines BL, so as to form the second structures S2 that include the free layers FL, the bit lines BL, and the spacers SW. The second structures S2 extend in the second direction D2 and are spaced apart from each other in the first direction D1. In each second structure S2, the bit line BL crosses over a plurality of the SAF structures SAF in the second direction D2, the free layers FL are formed between the bit line BL and the SAF structures SAF, and the spacers SW are respectively formed on the opposite sidewalls of the bit line BL. The free layers FL may be formed at an intersection where the bit line BL and the word line WL intersect, and the spacers SW may include portions covering first sidewalls of the free layers FL that are opposite to each other in the first direction D1.

The bit lines BL may include conductive materials, such as metal, metal alloys, and so on. The metal and the metal alloys may include, for instance, Cu, Al, Ti, Ta, W, Pt, Cr, Mo, or alloys thereof. The spacers SW may include appropriate materials, such as oxides, nitrides, or combinations thereof.

Next, with reference to FIG. 5 and FIG. 6, portions of the barrier material layer BML exposed by the second structures S2 are removed to form a plurality of barrier layers TBL that extend in the second direction D2 and are spaced apart from each other in the first direction D1. Since the spacers SW on the opposite sidewalls of the bit line BL include the portions covering the first sidewalls of the free layers FL that are opposite to each other in the first direction D1, during the process of manufacturing the barrier layers TBL, damages to the barrier layers TBL resulting from the IBE are away from portions of the free layers FL overlapping the bit line BL (i.e., the effective region) and do not affect the performance of the semiconductor device. In some embodiments, the portions of the spacers SW cover top surfaces of the underlaying barrier layers TBL, so that re-deposition contamination caused by the IBE may also be avoided because the top surfaces of the barrier layers TBL are covered by the spacers SW.

In some embodiments, in the process of removing the portions of the barrier material layer BML exposed by the second structures S2, portions of the SAF structures SAF below the exposed portions of the barrier material layer BML are also removed, causing the SAF structure SAF in each first structure S1 to form a plurality of SAF structures SAF′ that are spaced apart from each other in the first direction D1.

The semiconductor device 10 is described below with reference to FIG. 6, FIG. 7A, and FIG. 7B. The semiconductor device 10 may be formed by applying the manufacturing method described above, which should however not be construed as a limitation in the disclosure.

With reference to FIG. 6, FIG. 7A, and FIG. 7B, the semiconductor device 10 includes the first structures S1, the second structures S2, and the barrier layers TBL between the first structures S1 and the second structures S2. The first structures S1 extend in the first direction D1 and are spaced apart from each other in the second direction D2 intersecting the first direction D1. Each first structure S1 includes a word line WL, a selector OTS on the word line WL, and at least one SAF structure SAF′ on the selector OTS. The second structures S2 are disposed above the first structures S1, extend in the second direction D2, and are spaced apart from each other in the first direction D1. Each second structure S2 includes the bit line BL that crosses over the at least one SAF structure SAF′ in the second direction D2, the free layers FL between the bit line BL and the at least one SAF structure SAF′, and the spacers SW on the opposite sidewalls of the bit line BL. The free layers FL are disposed at the intersection where the bit line BL and the word line WL intersect, and the spacers SW include portions covering the first sidewalls of the free layers FL that are opposite to each other in the first direction D1. In some embodiments, the portions of the spacers SW cover the top surfaces of the underlying barrier layers TBL. In some embodiments, the portions of the spacers SW overlap the barrier layers TBL and the at least one SAF structure SAF′ in the third direction D3 perpendicular to the first direction D1 and the second direction D2. The barrier layers TBL extend in the second direction D2 and are spaced apart from each other in the first direction D1. In some embodiments, the barrier layers TBL include sidewalls that are coplanar with the sidewall of the at least one SAF structure SAF′.

In some embodiments, in each first structure S1, the number of the at least one SAF structure SAF′ may be plural, and the SAF structures SAF′ extend in the second direction D2 and are spaced apart from each other in the first direction D1.

In some embodiments, the semiconductor device 10 further includes a plurality of insulation layers IL. Each insulation layer IL is located below the bit line BL and between the free layers FL, where the insulation layers IL cover the second sidewalls of the free layers FL that are opposite to each other in the second direction D2. In some embodiments, the insulation layers IL may include insulation materials, such as oxides (e.g., silicon oxide), nitrides (e.g., silicon nitride), or combinations thereof.

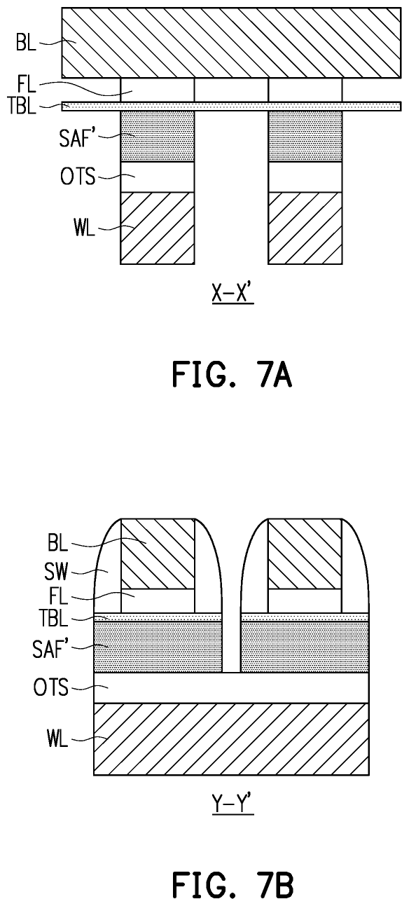

FIG. 8 is a schematic cross-sectional view of a semiconductor device according to another embodiment of the disclosure. A semiconductor device 20 shown in FIG. 8 is similar to the semiconductor device 10 shown in FIG. 6, and the differences therebetween lie in that the second structures S2 do not include any spacer SW in the present embodiment, the barrier layers TBL′ are spaced apart from each other in the first direction D1 and the second direction D2, and the SAF structures SAF extend in the first direction D1 and are spaced apart from each other in the second direction D2. For the sake of clarity in explanation, the insulation layers IL depicted in FIG. 6 are omitted in FIG. 8.

With reference to FIG. 8, the semiconductor device 20 includes the first structures S1, the second structures S2, and the barrier layers TBL′. The first structures S1 extend in the first direction D1 and are spaced apart from each other in the second direction D2 intersecting the first direction D1. Each first structure S1 includes the word line WL, the selector OTS on the word line WL, and the SAF structure SAF on the selector OTS. The second structures S2 are disposed above the first structures S1, extend in the second direction D2, and are spaced apart from each other in the first direction D1. Each second structure S2 includes the bit line BL that crosses over a plurality of the SAF structures SAF in the second direction D2 and the free layers FL between the bit line BL and the SAF structures SAF. The free layers FL are disposed at the intersection where the bit line BL and the word line WL intersect. The barrier layers TBL′ are spaced apart from each other in the first direction D1 and the second direction D2, and each barrier layer TBL′ is disposed between one of the first structures S1 and one of the second structures S2. In some embodiments, the free layers FL and the barrier layers TBL′ may be formed by performing following steps. First, a barrier material layer (e.g., the barrier material layer BML in FIG. 3) and a free material layer (not shown) are sequentially formed on the first structures S1. Then, the free material layer and the barrier material layer BML are patterned simultaneously with use of a mask which is the same as the mask used to form the free layers FL shown in FIG. 4, so as to form the free layers FL and the barrier layers TBL′.

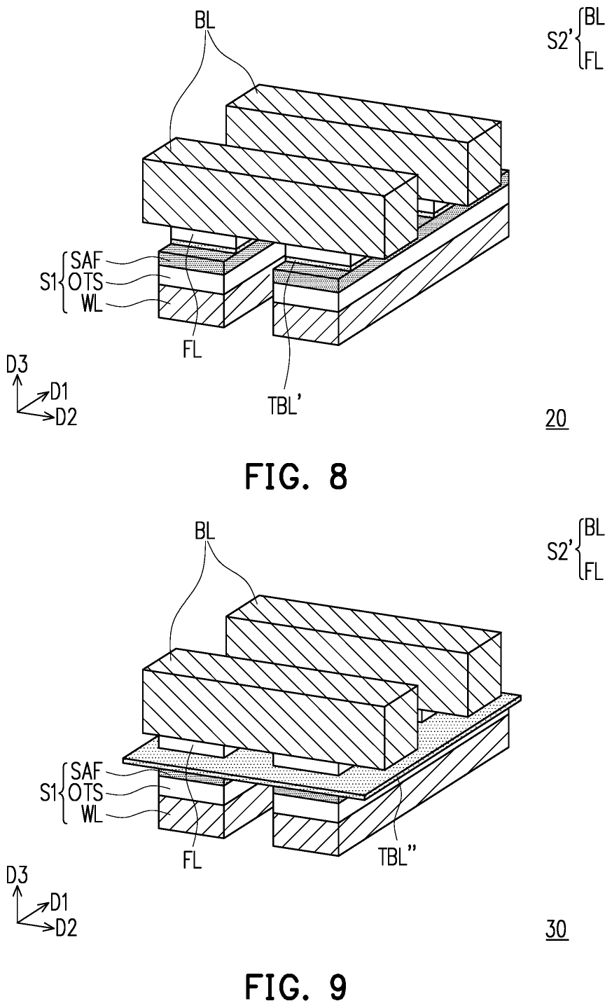

FIG. 9 is a schematic cross-sectional view of a semiconductor device according to another embodiment of the disclosure. A semiconductor device 30 shown in FIG. 9 is similar to the semiconductor device 20 shown in FIG. 8, and the difference therebetween lies in that a barrier layer TBL″ provided in this embodiment is a continuous single film layer.

With reference to FIG. 9, the semiconductor device 30 includes the first structures S1, the second structures S2, and the barrier layer TBL″ between the first structures S1 and the second structures S2. The first structures S1 extend in the first direction D1 and are spaced apart from each other in the second direction D2 intersecting the first direction D1. Each first structure S1 includes the word line WL, the selector OTS on the word line WL, and the SAF structure SAF on the selector OTS. The second structures S2 are disposed above the first structures S1, extend in the second direction D2, and are spaced apart from each other in the first direction D1. Each second structure S2 includes the bit line BL that crosses over a plurality of the SAF structures SAF in the second direction D2 and the free layers FL between the bit line BL and the SAF structures SAF. The free layers FL are disposed at the intersection where the bit line BL and the word line WL intersect. In some embodiments, the barrier layer TBL″ may be formed by performing following steps. First, after the free layers are formed on the barrier material layer BML as shown in FIG. 4, the bit line BL that crosses over the SAF structures SAF and the free layers FL is formed on the free layers FL, and no additional patterning process is performed on the barrier material layer BML, so as to form the barrier layer TBL″ as shown in FIG. 9. This may avoid damages to the barrier layer TBL″ caused by the IBE and re-deposition contamination caused by the IBE.

To sum up, in the semiconductor device and the manufacturing method thereof according to one or more of the embodiments of the disclosure, the spacers on the opposite sidewall of the bit line include the portions covering the first sidewalls of the free layers that are opposite to each other in the first direction. As such, during the process of manufacturing the barrier layer, damages to the barrier layer by the IBE are far from the region of the free layer overlapping the bit line (i.e., the effective region), and thus the performance of the semiconductor device remains unaffected.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A semiconductor device, comprising:
a plurality of first structures, extending in a first direction and spaced apart from each other in a second direction intersecting the first direction, each of the first structures comprising a word line, a selector on the word line, and at least one synthetic antiferromagnetic structure on the selector;
a plurality of second structures, disposed above the first structures, extending in the second direction, and spaced apart from each other in the first direction, each of the second structures comprising a bit line crossing over a plurality of the synthetic antiferromagnetic structures in the second direction, a plurality of free layers between the bit line and the synthetic antiferromagnetic structures, and a plurality of spacers on opposite sidewalls of the bit line, wherein the free layers are disposed at an intersection where the bit line and the word line intersect, and the spacers comprise portions covering first sidewalls of the free layers that are opposite to each other in the first direction; and
a plurality of barrier layers, disposed between the first structures and the second structures, extending in the second direction, and spaced apart from each other in the first direction.

2. The semiconductor device according to claim 1, wherein the portions of the spacers cover top surfaces of the underlying barrier layers.

3. The semiconductor device according to claim 1, wherein in each of the first structures, the number of the at least one synthetic antiferromagnetic structure is plural, and the synthetic antiferromagnetic structures are spaced apart from each other in the first direction.

4. The semiconductor device according to claim 3, wherein the portions of the spacers are overlapped with the barrier layers and the synthetic antiferromagnetic structures in a third direction perpendicular to the first direction and the second direction.

5. The semiconductor device according to claim 3, wherein the barrier layers comprise sidewalls coplanar with sidewalls of the synthetic antiferromagnetic structures.

6. The semiconductor device according to claim 1, further comprising:
a plurality of insulation layers, wherein each of the insulation layers is disposed below the bit line and between the free layers, and the insulation layers cover second sidewalls of the free layers that are opposite to each other in the second direction.

7. A semiconductor device, comprising:
a plurality of first structures, extending in a first direction and spaced apart from each other in a second direction intersecting the first direction, each of the first structures comprising a word line, a selector on the word line, and a synthetic antiferromagnetic structure on the selector;
a plurality of second structures, disposed above the first structures, extending in the second direction, and spaced apart from each other in the first direction, each of the second structures comprising a bit line crossing over a plurality of the synthetic antiferromagnetic structures in the second direction and a plurality of free layers between the bit line and the synthetic antiferromagnetic structures, wherein the free layers are disposed at an intersection where the bit line and the word line intersect; and
at least one barrier layer, disposed between the first structures and the second structures.

8. The semiconductor device according to claim 7, wherein the at least one barrier layer is a continuous single film layer.

9. The semiconductor device according to claim 7, wherein the number of the at least one barrier layer is plural, the barrier layers are spaced apart from each other in the first direction and the second direction, and each of the barrier layers is disposed between one of the first structures and one of the second structures.

10. A manufacturing method of a semiconductor device, comprising:
forming a plurality of first structures, wherein the first structures extend in a first direction and are spaced apart from each other in a second direction intersecting the first direction, and each of the first structures comprises a word line, a selector on the word line, and at least one synthetic antiferromagnetic structure on the selector;
forming a barrier material layer covering the first structures;
forming a plurality of second structures on the barrier material layer, wherein the second structures extend in the second direction and are spaced apart from each other in the first direction, each of the second structures comprises a bit line crossing over a plurality of the synthetic antiferromagnetic structures in the second direction, a plurality of free layers between the bit line and the synthetic antiferromagnetic structures, and a plurality of spacers respectively located on opposite sidewalls of the bit line, wherein the free layers are formed at an intersection where the bit line and the word line intersect, and the spacers comprise portions covering first sidewalls of the free layers that are opposite to each other in the first direction; and
removing a portion of the barrier material layer exposed by the second structures to form a plurality of barrier layers, wherein the barrier layers extend in the second direction and are spaced apart from each other in the first direction.

11. The manufacturing method according to claim 10, wherein the portions of the spacers cover top surfaces of the underlying barrier layers.

12. The manufacturing method according to claim 10, further comprising:
in the step of removing the portion of the barrier material layer exposed by the second structures, portions of the SAF structures located below the removed portion of the barrier material layer are also removed, so that the at least one synthetic antiferromagnetic structure in each of the first structures becomes a plurality of the synthetic antiferromagnetic structures that are spaced apart from each other in the first direction.
